(19) United States
(12) Patent Application Publication
(10) Pub. No.: US 2026/0026402 A1
(43) Pub. Date: Jan. 22, 2026

(54) SEMICONDUCTOR PACKAGE INCLUDING LOGIC DIE ALONGSIDE BUFFER DIE AND MANUFACTURING METHOD FOR THE SAME

(71) Applicant: SAMSUNG ELECTRONICS CO., LTD., SUWON-SI (KR)

(72) Inventors: HYUNSOO CHUNG, Suwon-si (KR); HYUNGGIL BAEK, Suwon-si (KR)

(21) Appl. No.: 19/028,858

(22) Filed: Jan. 17, 2025

(30) Foreign Application Priority Data
Jul. 16, 2024 (KR) 10-2024-0093857

(51) Int. Cl. H01L 25/16; H01L 21/3105; H01L 21/48; H01L 21/56; H01L 23/00; H01L 23/29; H01L 23/31; H01L 23/48; H01L 23/538; H10B 80/00; H10D 80/30

(52) U.S. Cl. CPC H01L 25/16; H01L 21/31051; H01L 21/486; H01L 21/56; H01L 23/3185; H01L 23/481; H01L 23/5385; H01L 24/08; H01L 24/16; H10B 80/00; H10D 80/30; H01L 23/291; H01L 24/05; H01L 24/80; H01L 2224/05624; H01L 2224/05647; H01L 2224/08145; H01L 2224/08225; H01L 2224/16227; H01L 2224/80895; H01L 2224/80896; H01L 2924/1431; H01L 2924/14361

(57) ABSTRACT

A semiconductor package includes a wiring structure. A buffer die is disposed on the wiring structure. A logic die is disposed alongside the buffer die on the wiring structure. A first encapsulating material covers at least a portion of each of the buffer die and the logic die. A memory stack is disposed on the buffer die and is electrically connected to the buffer die. A bridge die is disposed so as to extend over at least a portion of each of the buffer die and the logic die, and is electrically connected to each of the buffer die and the logic die. A second encapsulating material covers at least a portion of each of the memory stack and the bridge die. The buffer die and the logic die are disposed at a level that is between those of the wiring structure and the bridge die.

### CROSS-REFERENCE TO RELATED APPLICATION

This application claims priority under 35 U.S.C. § 119 to Korean Patent Application No. 10-2024-0093857 filed in the Korean Intellectual Property Office on Jul. 16, 2024, the entire contents of which are herein incorporated by reference.

### TECHNICAL FIELD

The present disclosure relates to a semiconductor package and, more specifically, to a semiconductor package including a logic die alongside a buffer die and a manufacturing method for the same.

### DISCUSSION OF THE RELATED ART

In the semiconductor industry, high bandwidth memory (HBM) is a well-established technology designed to deliver high data bandwidth and increased memory capacity. This is achieved by stacking multiple core dies (such as, DRAMs) on a buffer die. HBM is typically manufactured using a chip-on-wafer (CoW) process, where the core dies are stacked in a lower wafer, which serves as the buffer die. The core dies are interconnected by through-silicon vias (TSVs), and the process concludes with the sawing of the lower wafer.

### SUMMARY OF THE INVENTION

TA semiconductor package includes a wiring structure. A buffer die is disposed on the wiring structure. A logic die is disposed alongside the buffer die on the wiring structure. A first encapsulating material covers at least a portion of each of the buffer die and the logic die. A memory stack is disposed on the buffer die and is electrically connected to the buffer die, a bridge die that extends over at least a portion of each of the buffer die and the logic die, and is electrically connected to each of the buffer die and the logic die, and a second encapsulating material that covers at least a portion of each of the memory stack and the bridge die. The buffer die and the logic die are disposed at a level between those of the wiring structure and the bridge die.

A semiconductor package includes a first wiring structure. A buffer die is disposed on the first wiring structure, and includes first through-vias and second through-vias. A logic die is disposed alongside the buffer die on the first wiring structure, and includes third through-vias. A first encapsulating material covers at least a portion of each of the buffer die and the logic die. Via pads are disposed on the first encapsulating material, and include first via pads connected to the first through-vias, second via pads connected to the second through-vias, and third via pads connected to the third through-vias. A memory stack is disposed on the first encapsulating material, and includes first connection pads electrically connected to the first via pads. A bridge die is disposed alongside the memory stack on the first encapsulating material, and includes second connection pads and third connection pads electrically connected to the second via pads and the third via pads, respectively. A second encapsulating material covers at least a portion of each of the memory stack and the bridge die.

A semiconductor package manufacturing method includes disposing a buffer die alongside a logic die. The buffer die includes first through-vias and second through-vias. The logic die includes third through-vias. The buffer die and the logic die are encapsulated with a first encapsulating material. Via pads are formed on the first encapsulating material. The via pads include first via pads connected to the first through-vias, second via pads connected to the second through-vias, and third via pads connected to the third through-vias. A memory stack is disposed on the first encapsulating material such that first connection pads of the memory stack are electrically connected to the first via pads. A bridge die is disposed on the first encapsulating material such that second connection pads and third connection pads of the bridge die are electrically connected to the second via pads and the third via pads, respectively. A second encapsulating material is formed covering at least a portion of each of the memory stack and the bridge die. A wiring structure is formed to be electrically connected to the buffer die and the logic die.

### BRIEF DESCRIPTION OF THE DRAWINGS

A more complete appreciation of the present disclosure and many of the attendant aspects thereof will be readily obtained as the same becomes better understood by reference to the following detailed description when considered in connection with the accompanying drawings, wherein:

FIG. 1 is a cross-sectional view of a semiconductor package according to an embodiment.

FIG. 2 is a cross-sectional view of a semiconductor package according to an embodiment.

FIG. 3 is a cross-sectional view of a semiconductor package according to an embodiment.

FIG. 4 is a cross-sectional view of a semiconductor package according to an embodiment.

FIG. 5 is a cross-sectional view of a semiconductor package according to an embodiment.

FIG. 6 is a cross-sectional view of a semiconductor package according to an embodiment.

FIGS. 7 to 15 are views illustrating a process of manufacturing a semiconductor package according to an embodiment.

### DETAILED DESCRIPTION OF THE EMBODIMENTS

In the following detailed description, embodiments of the present disclosure have been shown and described, simply by way of illustration. The present disclosure can be variously implemented and is not necessarily limited to the following embodiments.

While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like. Like reference numerals may designate like elements throughout the specification and the drawings.

Throughout this specification, when a part is referred to as being “connected” to another part, it may be directly connected to the other part, or may be connected to the other part indirectly with any other elements interposed therebetween. From a similar point of view, when a part is referred to as being “connected” to another part, it may be physically connected to the other part, or may be electrically connected to the other part.

Further, it will be understood that when an element such as a layer, film, region, or substrate is referred to as being “on” another element, it can be directly on the other element or intervening elements may also be present. In contrast, when an element is referred to as being “directly on” another element, there are no intervening elements present. Further, when an element is “on” a reference portion, the element is located above or below the reference portion, and it does not necessarily mean that the element is located “above” or “on” in a direction opposite to gravity.

In addition, unless explicitly described to the contrary, the words “comprise” and “include”, and variations such as “comprises” or “comprising”, “includes” or “including” will be understood to imply the inclusion of stated elements but not the exclusion of any other elements.

Further, in the entire specification, when it is referred to as “on a plane”, or “in a plan view” it means when a target part is viewed from above, and when it is referred to as “on a cross-section”, it means when the cross-section obtained by cutting a target part vertically is viewed from the side.

Furthermore, throughout this specification, the ordinal numbers such as first, second, or the like are used to distinguish an element from other elements identical or similar to the corresponding element, and are not necessarily intended to indicate a particular element. Accordingly, an element termed as a first element in a part of this specification may be termed as a second element in other parts of this specification.

Further, throughout this specification, elements expressed in the singular forms are intended to include the plural forms as well unless the context clearly indicates otherwise. For example, an insulating layer may be used to refer to not only one insulating layer but also a plurality of insulating layers, such as two, three, or more.

Example embodiments of the present invention relate to a semiconductor package design and its manufacturing method aimed at improving device thickness reduction and heat dissipation while maintaining high performance and efficient connections.

According to this approach a compact design may be achieved by the novel arrangement of the constituent elements. In particular, the semiconductor package includes components like a buffer die, logic die, memory stack, and bridge die arranged to minimize thickness. The bridge die is placed alongside the memory stack and is connected to both the buffer die and the logic die.

Enhanced heat dissipation may also be achieved by this design. Heat generated by the logic and buffer dies is dissipated through the bridge die and optional dummy dies or heat dissipation structures.

The package uses advanced features like through-vias, via pads, and hybrid bonding to ensure reliable and high-speed connections between components (e.g., memory stack, logic die, and wiring structure).

Methods such as encapsulation, dry etching, and chemical mechanical polishing (CMP) are used to form the package layers, enabling the exposure of through-vias and precise interconnections.

The package includes encapsulation materials and wiring structures that protect components and provide electrical pathways, ensuring durability and functionality.

By using these approaches, the overall height of the semiconductor package may be reduced, making it suitable for modern compact devices. By optimizing heat dissipation pathways, the package ensures better performance and longevity. Moreover, the described processes facilitate efficient production of advanced semiconductor devices.

This innovation is particularly relevant for high-performance computing, mobile devices, and systems requiring high bandwidth memory (HBM) and logic integration.

Hereinafter, semiconductor packages according to embodiments of the present disclosure will be described with reference to the drawings.

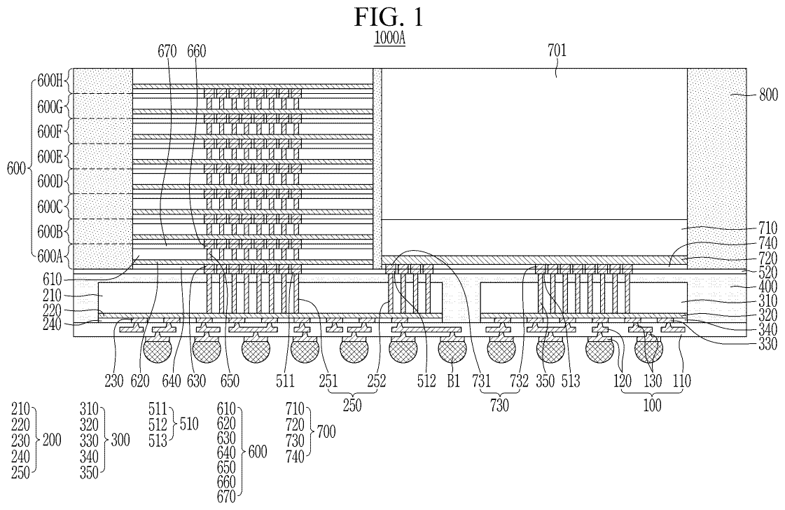

FIG. 1 is a cross-sectional view of a semiconductor package according to an embodiment.

A semiconductor package 1000A, according to an embodiment, includes a wiring structure 100, a buffer die 200 that is disposed on the wiring structure 100, a logic die 300 that is disposed alongside the buffer die 200 on the wiring structure 100, a first encapsulating material 400 that covers at least a portion of each of the buffer die 200 and the logic die 300, a memory stack 600 that is disposed on the buffer die 200, a bridge die 700 that is disposed so as to extend over at least a portion of each of the buffer die 200 and the logic die 300, and a second encapsulating material 800 that covers at least a portion of each of the memory stack 600 and the bridge die 700. The second encapsulating material 800 may be in contact with side surfaces of the memory stack 600 and the bridge die 700. The bridge die 700 and the logic die 300 might not be in direct contact with the memory stack 600.

As used herein, the phrase “alongside” is meant to convey that the two described elements are arranged side-by-side such that they may be proximate to one another and may share common top and bottom surface levels with respect to the stack. Thus, the buffer die 200 and the logic die 300 may be so arranged.

The wiring structure 100 may be electrically connected to the buffer die 200 and the logic die 300, and may include insulating layers 110, wiring layers 120, and vias 130.

The first insulating layers 110 may be disposed between the wiring layers 120, thereby preventing an electric short between them. The first insulating layers 110 may have recognizable boundaries with respect to each other or might not have visible boundaries, depending on their materials, the manufacturing process, etc. n insulating material of the first insulating layers 110 may be, for example, a thermosetting resin such as polyimide, a thermoplastic resin such as epoxy, an organic material such as a photo-imageable dielectric (PID), or an inorganic material such as a silicon oxide or a silicon nitride.

The wiring layers 120 may include at least one wiring pattern, and the wiring patterns may be connected to one another to be able to perform various functions according to the design. For example, the wiring layers 120 may include at least one of signal lines for performing a signal transfer function, power lines for performing a power transfer function, and ground lines for performing a ground function. Among the wiring layers 120, the uppermost wiring layer and the lowermost wiring layer may include pads for electrical connections with other components. For example, the uppermost wiring layer may include pads for electrical connections with the buffer die 200 and the logic die 300, and the lowermost wiring layer may include pads for electrical connections with first conductive bumps B1. The number of wiring layers 120 is not necessarily limited to what is shown herein, and may be more or less than shown in the drawing. As the material of the wiring layers 120, an electrically conductive material may be used, and for example, copper (Cu), aluminum (Al), gold (Au), silver (Ag), platinum (Pt), tin (Sn), chromium (Cr), palladium (Pd), lead (Pb), titanium (Ti), tungsten (W), or an alloy thereof may be used.

The vias 130 may penetrate through the insulating layers 110, and may electrically connect the wiring layers 120 positioned in different layers to each other or electrically connect the wiring layers 120 to the buffer die 200 or the logic die 300. In the embodiment, among the vias 130, vias disposed on the uppermost side may be in contact with and may be electrically connected to the buffer die 200 and the logic die 300, respectively. The vias 130 may have a tapered shape or a columnar shape whose width decreases from one side toward the other side, but are not necessarily limited thereto. As the material of the vias 130, a conductive material may be used, and the same material as the material of the wiring layers 120 may be used. Depending on the manufacturing process, the vias 130 may be formed integrally with the wiring layers 120 such that no boundary exists between them.

As will be described below, after the buffer die 200 and the logic die 300 are disposed and encapsulated with the first encapsulating material 400 on a carrier substrate 10 and the carrier substrate 10 is removed, the wiring structure 100 may be formed. The wiring structure 100 may be directly formed on the surface of each of the buffer die 200, the logic die 300, and the first encapsulating material 400 from which the carrier substrate 10 has been removed, so as to be in contact with each of them, and the individual surfaces of the buffer die 200, the logic die 300, and the first encapsulating material 400 which are in contact with the wiring structure 100 may be coplanar. Alternatively, the wiring structure 100 may be directly and electrically connected to the buffer die 200 and the logic die 300 without other components such as the conductive bumps.

As shown in the drawing, on the wiring structure 100, the buffer die 200 and the logic die 300 are disposed, and on the buffer die 200 and the logic die 300, the memory stack 600 and the bridge die 700 are additionally disposed. Accordingly, it will be appreciated that the buffer die 200 and the logic die 300 are disposed at a level between those of the wiring structure 100 and the bridge die 700. Alternatively, the buffer die 200 and the logic die 300 are disposed at a level between those of the wiring structure 100 and the memory stack 600. The bridge die 700 and the memory stack 600 may be disposed adjacent to each other.

The buffer die 200 and the memory stack 600 may constitute a high bandwidth memory (HBM). The buffer die 200 may perform a function of ensuring data transfer integrity through data buffering, a function of efficiently distributing signals and power to the memory stack, etc. The buffer die 200 may be a logic die, and may be referred to as the base die in the art to which the present disclosure pertains.

The buffer die 200 may be electrically connected to each of the wiring structure 100, the memory stack 600, and the bridge die 700, and may include a semiconductor substrate 210, a circuit structure 220, connection pads 230, an insulating layer 240, and through-vias 250.

The type of the semiconductor substrate 210 is not necessarily limited to what is shown and described herein, and may include a semiconductor element such as silicon (Si) or germanium (Ge), or a compound semiconductor such as gallium arsenide (GaAs) or indium arsenide (InAs).

The circuit structure 220 may be formed on the lower surface of the semiconductor substrate 210, and may include circuit devices (for example, transistors such as metal-oxide semiconductor field-effect transistors (MOSFETs), etc.), internal wiring layers, interlayer insulating layers, and the like which are formed through front-end-of-line (FEOL) and back-end-of-line (BEOL) processes.

The connection pads 230 may be positioned on the lower surface of the buffer die 200. For example, the buffer die 200 may face down such that the lower surface on which the connection pads 230 are disposed face the wiring structure 100. The connection pads 230 may be electrically connected to the circuit structure 220 of the buffer die 200, and may electrically connect the buffer die 200 to the wiring structure 100. The connection pads 230 may include a conductive material such as copper (Cu) or aluminum (Al).

The insulating layer 240 may perform a function of physically and chemically protecting the surface of the buffer die 200, a function of stabilizing the electrical characteristics, and the like. For electrical connections of the buffer die 200, the insulating layer 240 might not cover some or all of the connection pads 230. The insulating layer 240 may include an insulating material, and may include, for example, a silicon oxide or a silicon nitride.

The through-vias 250 may be electrically connected to the circuit structure 220, and may include first through-vias 251 that electrically connect the buffer die 200 to the memory stack 600, and second through-vias 252 that electrically connect the buffer die 200 to the bridge die 700. The first-through vias 251 and the second through-vias 252 may be disposed adjacent to each other. The first through vias 251 may be disposed below the memory stack 600, and the second through vias 252 may be disposed below the bridge die 700. The through-vias 250 may penetrate through the semiconductor substrate 210, and may further penetrate through at least a portion of the circuit structure 220 depending on the process. The through-vias 250 may include a conductive material such as copper (Cu), tungsten (W), silver (Ag), nickel (Ni), or polysilicon.

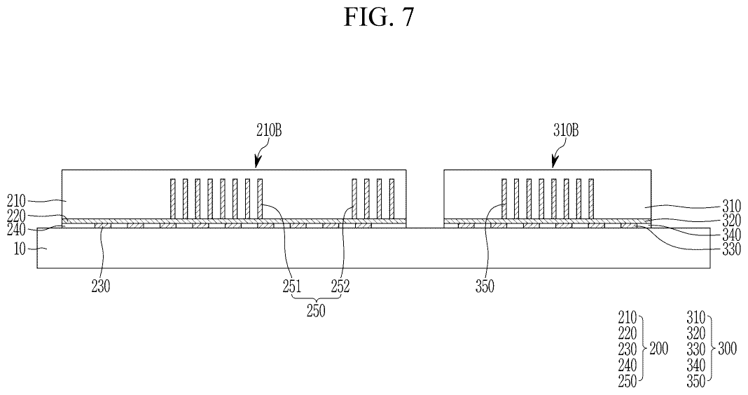

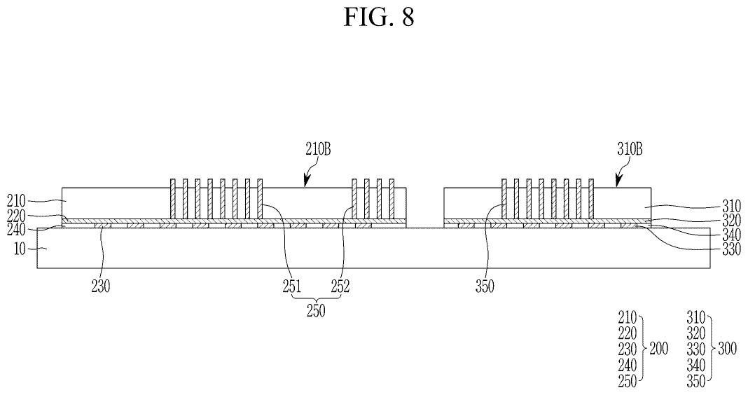

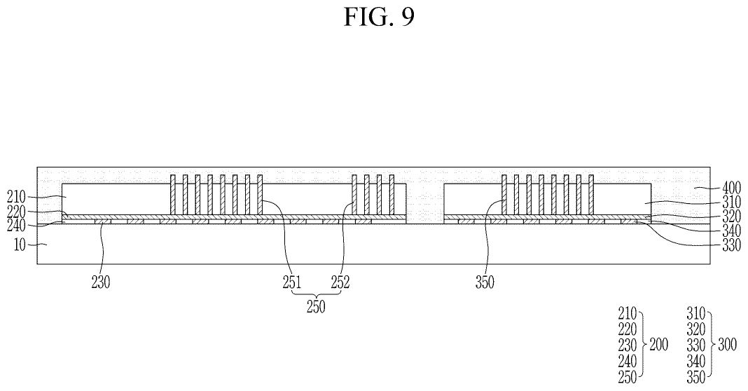

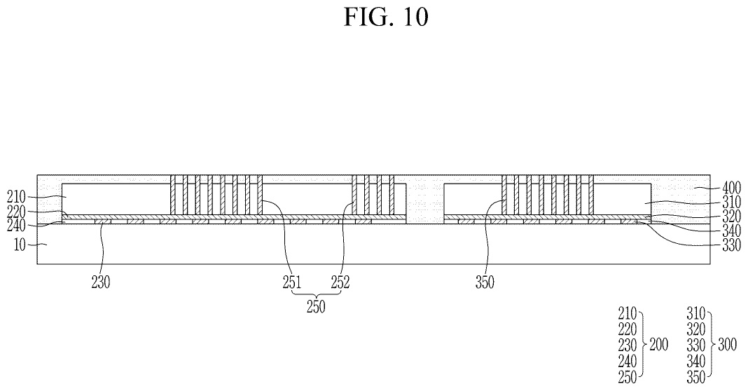

A portion (the upper area in the drawing) of each of the first through-vias 251 and the second through-vias 252 may protrude upward from the buffer die 200. Since a portion of the semiconductor substrate 210 in the thickness direction is removed by processing on the back surface 210B of the semiconductor substrate 210 as will be described below, a portion of each of the first through-vias 251 and the second through-vias 252 may have a structure protruding upward from the buffer die 200 (see FIGS. 7 and 8). Further, the protruding region of each of the first through-vias 251 and the second through-vias 252 may be covered by the first encapsulating material 400 and be ground together with the first encapsulating material 400, thereby being exposed from the upper surface of the first encapsulating material 400 (see FIGS. 9 and 10). As a result of the grinding, the upper surface of each of the first through-vias 251 and the second through-vias 252 may be coplanar with the upper surface of the first encapsulating material 400.

Between each of the first through-vias 251 and the second through-vias 252 and the semiconductor substrate 210, an insulating barrier film may be additionally interposed. The insulating barrier film may include an insulating material such as a silicon oxide, a silicon nitride, or benzocyclobutene (BCB). Also, the insulating barrier film may be interposed so as to extend between each of the first through-vias 251 and the second through-vias 252 and the first encapsulating material 400.

The logic die 300 may be electrically connected to each of the wiring structure 100 and the bridge die 700, and may include a semiconductor substrate 310, a circuit structure 320, connection pads 330, an insulating layer 340, and third through-vias 350.

The type of the semiconductor substrate 310 is not necessarily limited to what is described herein, and may include a semiconductor element such as silicon (Si) or germanium (Ge), or a compound semiconductor such as gallium arsenide (GaAs) or indium arsenide (InAs).

The circuit structure 320 may be formed on the lower surface of the semiconductor substrate 310, and may include circuit devices (for example, transistors such as MOSFETs, etc.), internal wiring layers, interlayer insulating layers, and the like which are formed through front-end-of-line (FEOL) and back-end-of-line (BEOL) processes.

The connection pads 330 may be positioned on the lower surface of the logic die 300. For example, the logic die 300 may be disposed face down such that the lower surface on which the connection pads 330 are disposed faces the wiring structure 100. The connection pads 330 may be electrically connected to the circuit structure 320 of the logic die 300, and may electrically connect the logic die 300 to the wiring structure 100. The connection pads 330 may include a conductive material such as copper (Cu) or aluminum (Al).

The insulating layer 340 may perform a function of physically and chemically protecting the surface of the logic die 300, a function of stabilizing the electrical characteristics, and the like. For electrical connections of the logic die 300, the insulating layer 340 might not cover some or all of the connection pads 330. The insulating layer 340 may include an insulating material, and may include, for example, a silicon oxide or a silicon nitride.

The third through-vias 350 may be electrically connected to the circuit structure 320, and may electrically connect the logic die 300 to the bridge die 700. The third through-vias 350 may penetrate through the semiconductor substrate 310, and may further penetrate through at least a portion of the circuit structure 320 depending on the process. For example, the third though vias 350 may be disposed below a corresponding third via pads 513. The third through-vias 350 may include a conductive material such as copper (Cu), tungsten (W), silver (Ag), nickel (Ni), or polysilicon.

A portion of each third through-via 350 (e.g., the upper region in the drawing) may protrude upward from the logic die 300. Since a portion of the semiconductor substrate 310 is removed by processing on the back surface 310B of the semiconductor substrate 310 as will be described below, a portion of each third through-via 350 may have a structure protruding upward from the logic die 300 (see FIGS. 7 and 8). Further, the protruding region of each third through-via 350 may be covered by the first encapsulating material 400 and be ground together with the first encapsulating material 400, thereby being exposed from the upper surface of the first encapsulating material 400 (see FIGS. 9 and 10). As a result of the grinding, the upper surface of each third through-via 350 may be coplanar with the upper surface of the first encapsulating material 400, similar to the first through-vias 251 and the second through-vias 252.

Between each third through-via 350 and the semiconductor substrate 310, an insulating barrier film may be additionally interposed. The insulating barrier film may include an insulating material such as a silicon oxide, a silicon nitride, or benzocyclobutene (BCB). Also, the insulating barrier film may be interposed so as to extend between each third through-via 350 and the first encapsulating material 400.

The type of the logic die 300 is not necessarily limited to what is described herein, and the logic die 300 may include one or more of central processing units (CPUs), graphic processing units (GPUs), neutral processing units (NPUs), application specific integrated circuits (ASICs), application processors (APs), microprocessors, or systems-on-chip (SoCs).

The thickness of the logic die 300 may be 30 μm to 100 μm, inclusive.

The first encapsulating material 400 may perform a function of physically and chemically protecting the buffer die 200 and the logic die 300. The first encapsulating material 400 may include an inorganic material such as a silicon oxide or a silicon nitride. On the first encapsulating material 400, an insulating layer 520 for bonding between the memory stack 600 and the bridge die 700 may be formed, and it may be preferable for the first encapsulating material 400 to include an inorganic material to prevent peeling from being caused by a difference from the insulating layer 520 in coefficient of thermal expansion (CTE), weak chemical bonding, etc. However, in some embodiments, the first encapsulating material 400 may include an organic material, for example, a thermoplastic resin such as epoxy molding compounds (EMCs) and epoxy resins, a thermosetting resin such as polyimide, etc.

The first encapsulating material 400 may extend to the upper surface of each of the buffer die 200 and the logic die 300 so as to cover at least a portion of the protruding region of each of the first through-vias 251, the second through-vias 252, and the third through-vias 350. The first encapsulating material 400 may extend to the upper surface of each of the buffer die 200 and the logic die 300 so as to cover the semiconductor substrates 210 and 310, thereby preventing the semiconductor substrates 210 and 310 from being contaminated by processing on the first encapsulating material 400 and/or the through-vias 250 and 350 during the process of grinding the first encapsulating material 400.

The semiconductor package 1000A may include via pads 510 for facilitating electrical connections between the buffer die 200 and the memory stack 600, between the buffer die 200 and the bridge die 700, and between the logic die 300 and the bridge die 700. The via pads 510 may be disposed on the first encapsulating material 400 and may be electrically connected to the through-vias 250 and 350. For example, the via pads 510 may include first via pads 511 that are connected to the first through-vias 251, second via pads 512 that are connected to the second through-vias 252, and third via pads 513 that are connected to the third through-vias 350. The first, second and third via pads 511, 512, and 513 may be in contact with the insulating layer 520 which extends over the memory stack 600 and the bridge die 700. The first via pads 511 may be disposed at a level between the wiring structure 100 and the memory stack. The second via pads 512 may be disposed at a level between the wiring structure 100 and the bridge die 700. The third via pads 513 may be disposed at a level between the wiring structure 100 and the bridge 700. A conductive material such as copper (Cu) or aluminum (Al) may be used in the material of the via pads 510.

The via pads 510 may be bonded to each of the memory stack 600 and the bridge die 700 by hybrid bonding. The hybrid bonding is a technology of directly bonding components to be connected to each other without the use of other intervening components (for example, solder bumps), enabling a decrease in the package thickness and an increase in signal transfer speed. During the hybrid bonding, among substances having different properties, such as metals and insulators, substances having the same properties may be bonded together. For example, the metals may be bonded to each other and the insulators may be bonded to each other. The via pads 510 may be in contact with connection pads 630 of a memory die 600A disposed at the bottom of the memory stack 600 or connection pads 730 of the bridge die 700, respectively, and be bonded thereto, respectively, by the hybrid bonding (for example, Cu—Cu bonding).

The semiconductor package 1000A may further include the insulating layer 520 that is disposed adjacent to the via pads 510 on the first encapsulating material 400, for hybrid bonding between the via pads 510 and each of the memory stack 600 and the bridge die 700. In the insulating layer 520, the via pads 510 may be embedded; however, the insulating layer 520 may expose at least some of the upper surfaces of the via pads 510 for electrical connections of the via pads 510. For example, the insulating layer 520 may be disposed at a level identical to or similar to the level of, for example, the via pads 510, so as to cover the side surfaces of the via pads 510 and so as not to cover the upper surfaces of the via pads 510. The insulating layer 520 may be in contact with and bonded to each of a first insulating layer 640 of the memory stack 600 and a third insulating layer 740 of the bridge die 700. For example, the first insulating layer 540 of the memory stack 600 and the third insulating layer 740 of the bridge die 700 may be disposed coplanar to each other, on the insulating layer 520. The insulating layer 520 may include an insulating material, and may include an inorganic material such as a silicon carbon nitride (SiCN), a silicon oxide, or a silicon nitride.

The memory stack 600 may include a plurality of memory dies 600A, 600B, 600C, 600D, 600E, 600F, 600G, and 600H stacked together, and may be electrically connected to the buffer die 200. The memory stack 600 is disposed on the buffer die 200, but may also be understood as being disposed on the first encapsulating material 400 as the first encapsulating material 400 extends to the upper surface of the buffer die 200. Between the memory stack 600 and the first encapsulating material 400, the via pads 510 and the insulating layer 520 may be interposed.

Each of the memory dies 600A, 600B, 600C, 600D, 600E, 600F, 600G, and 600H may be a dynamic random access memory (DRAM), and may be referred to as a core die, a slave die, etc., as known in the art to which the present disclosure pertains.

Each of the memory dies 600A, 600B, 600C, 600D, 600E, 600F, 600G, and 600H may include a semiconductor substrate 610, a circuit structure 620, connection pads 630, a first insulating layer 640, through-vias 650, via pads 660, and a second insulating layer 670. The number of memory dies 600A, 600B, 600C, 600D, 600E, 600F, 600G, and 600H is not necessarily limited to what is describe herein, and may be more or less than what is shown in the drawing. Among the memory dies, the memory die 600H disposed at the top might not include through-vias 650, via pads 660, and a second insulating layer 670 which are components for connections with an upper memory die.

In the embodiment, the individual memory dies 600A, 600B, 600C, 600D, 600E, 600F, 600G, and 600H may be bonded together by hybrid bonding. As a result of the hybrid bonding, the connection pads 630 of each of the memory dies 600B, 600C, 600D, 600E, 600F, 600G, and 600H may be in contact with and connected to the via pads 660 of another memory die disposed below it.

In the embodiment, the memory stack 600 may be bonded to the first via pads 511 by hybrid bonding. As a result of the hybrid bonding, the connection pads 630 of the memory die 600A disposed at the bottom among the memory dies may be in contact with and connected to the first via pads 511.

The type of the semiconductor substrate 610 is not necessarily limited to what is described herein, and may include a semiconductor element such as silicon (Si) or germanium (Ge), or a compound semiconductor such as gallium arsenide (GaAs) or indium arsenide (InAs).

The circuit structure 620 may be formed on the lower surface of the semiconductor substrate 610, and may include circuit devices (for example, transistors such as MOSFETs, etc.), internal wiring layers, interlayer insulating layers, and the like which are formed through front-end-of-line (FEOL) and back-end-of-line (BEOL) processes.

The connection pads 630 may be positioned on the lower surface of the memory die, and may be electrically connected to the circuit structure 620 of the memory die. The connection pads 630 of each of the memory dies 600B, 600C, 600D, 600E, 600F, 600G, and 600H may be electrically connected to the via pads 660 of the memory die disposed below it. Further, the connection pads 630 of the memory die 600A disposed at the bottom among the memory dies may be electrically connected to the first via pads 511. The connection pads 630 may include a conductive material such as copper (Cu) or aluminum (Al).

As described above, in the embodiment in which the memory dies 600A, 600B, 600C, 600D, 600E, 600F, 600G, and 600H are bonded together by hybrid bonding, the connection pads 630 of each of the memory dies 600B, 600C, 600D, 600E, 600F, 600G, and 600H may be in contact with and connected to the via pads 660 of the memory die disposed below it. Further, in the embodiment in which the memory stack 600 is bonded to the first via pads 511 by hybrid bonding, the connection pads 630 of the lowermost memory die 600A may be in contact with and connected to the first via pads 511.

The first insulating layer 640 may provide hybrid bonding between the memory die and other components, along with the connection pads 630. In the first insulating layer 640, the connection pads 630 are embedded; however, the first insulating layer 640 may expose at least some of the lower surfaces of the connection pads 630 for electrical connections of the connection pads 630. For example, the first insulating layer 640 may cover the side surfaces of the connection pads 630 but might not cover the lower surfaces of them. Each of the first insulating layers 640 of the memory dies 600B, 600C, 600D, 600E, 600F, 600G, and 600H may be in contact with and bonded to the second insulating layer 670 of the memory die disposed below it. Further, the first insulating layer 640 of the memory die 600A disposed at the bottom among the memory dies may be in contact with and bonded to the insulating layer 520. The first insulating layer 640 may include an insulating material such as a silicon carbon nitride (SiCN), a silicon oxide, or a silicon nitride.

The through-vias 650 may be electrically connected to the circuit structure 620, and may electrically connect the memory dies 600A, 600B, 600C, 600D, 600E, 600F, 600G, and 600H to one another. The through-vias 650 may penetrate through the semiconductor substrate 610, and may further penetrate through at least a portion of the circuit structure 620 depending on the process. The through-vias 650 may include a conductive material such as copper (Cu), tungsten (W), silver (Ag), nickel (Ni), or polysilicon.

Between the through-vias 650 and the semiconductor substrate 610, an insulating barrier film may be additionally interposed. The insulating barrier film may include an insulating material such as a silicon oxide, a silicon nitride, or benzocyclobutene (BCB).

The via pads 660 may be disposed on the semiconductor substrate 610, and be connected to the through-vias 650. The via pads 660 of each of the memory dies 600A, 600B, 600C, 600D, 600E, 600F, and 600G may be electrically connected to the connection pads 630 of the memory die disposed thereon. The via pads 660 may include a conductive material such as copper (Cu), aluminum (Al), tungsten (W), silver (Ag), nickel (Ni), or polysilicon.

The second insulating layer 670 may provide hybrid bonding between the memory die and another memory die, along with the via pads 660. In the second insulating layer 670, the via pads 660 are embedded; however, the second insulating layer 670 may expose at least some of the upper surfaces of the via pads 660 for electrical connections of the via pads 660. For example, the second insulating layer 670 may cover the side surfaces of the via pads 660 and might not cover the upper surfaces of them. Each of the second insulating layers 670 of the memory dies 600B, 600C, 600D, 600E, 600F, and 600G may be in contact with and bonded to the first insulating layer 640 of the memory die disposed thereon. The second insulating layer 670 may include an insulating material such as a silicon carbon nitride (SiCN), a silicon oxide, or a silicon nitride, similar to the first insulating layer 640.

The bridge die 700 may be disposed on at least a portion of each of the buffer die 200 and the logic die 300, and be electrically connected to each of the buffer die 200 and the logic die 300. The bridge die 700 is disposed so as to extend to at least a portion of the upper surface of each of the buffer die 200 and the logic die 300, but may also be understood as being disposed on the first encapsulating material 400 as the first encapsulating material 400 extends to the upper surfaces of the buffer die 200 and the logic die 300. For example, the first encapsulating material 400 may be disposed between the bridge die 700 and the buffer die 200, and between the bridge die 700 and the logic die 300. In the embodiment, the bridge die 700 may be disposed alongside the memory stack 600 on the first encapsulating material 400. Between the bridge die 700 and the first encapsulating material 400, the via pads 510 and the insulating layer 520 may be interposed.

The bridge die 700 may be electrically connected to each of the buffer die 200 and the logic die 300, thereby providing an electrical connection between them, and may include a semiconductor substrate 710, a circuit structure 720, connection pads 730, and a third insulating layer 740.

The type of the semiconductor substrate 710 is not necessarily limited to what is described herein, and may include a semiconductor element such as silicon (Si) or germanium (Ge), or a compound semiconductor such as gallium arsenide (GaAs) or indium arsenide (InAs).

The circuit structure 720 may be formed on the lower surface of the semiconductor substrate 710, and may include circuit devices (for example, transistors such as MOSFETs, etc.), internal wiring layers, interlayer insulating layers, and the like which are formed through front-end-of-line (FEOL) and back-end-of-line (BEOL) processes.

The connection pads 730 may be positioned on the lower surface of the bridge die 700. For example, connection pads 730 may be disposed below the circuit structure 720 of the bridge die 700. The connection pads 730 may be electrically connected to the circuit structure 720 of the bridge die 700, and may include second connection pads 731 that are electrically connected to the second via pads 512, and third connection pads 732 that are electrically connected to the third via pads 513. The bridge die 700 may be electrically connected to the buffer die 200 and the logic die 300 through the second via pads 512 and the third via pads 513, respectively. Each of the connection pads 730 may include a conductive material such as copper (Cu) or aluminum (Al).

In the embodiment, the bridge die 700 may be bonded to the second via pads 512 and the third via pads 513 by hybrid bonding. As a result of the hybrid bonding, the second connection pads 731 and the third connection pads 732 may be in contact with and connected to the second via pads 512 and the third via pads 513, respectively.

The third insulating layer 740 may provide hybrid bonding of the bridge die 700 with the second via pads 512 and the third via pads 513, along with the connection pads 730. In the third insulating layer 740, the connection pads 730 are embedded; however, the third insulating layer 740 may expose at least some of the lower surfaces of the connection pads 730 for electrical connections of the connection pads 730. For example, the third insulating layer 740 may cover the side surfaces of the connection pads 730 and might not cover the lower surfaces of them. The third insulating layer 740 may be in contact with and bonded to the insulating layer 520. The third insulating layer 740 may include an insulating material such as a silicon carbon nitride (SiCN), a silicon oxide, or a silicon nitride.

The area of the bridge die 700 which overlaps the logic die 300 may be larger than the area that overlaps the buffer die 200. For example, the bridge die 700 may overlap an entirety of the logic die 300. By increasing the area of the bridge die 700 overlapping the logic die 300, it is possible to further improve heat dissipation of the semiconductor package 1000A.

The thickness of the bridge die 700 may be equal to or smaller than 200 μm.

The second encapsulating material 800 may perform a function of physically and chemically protecting the memory stack 600 and the bridge die 700. The material of the second encapsulating material 800 is not necessarily limited to what is described herein, and thermoplastic resins such as epoxy molding compounds (EMCs) and epoxy resins, thermosetting resins such as polyimide, and the like which are usually used during die molding in the semiconductor package field may be used.

An embedded multi-die interconnect bridge (EMIB) structure is well-known in that a high bandwidth memory (HBM) and a logic die are disposed alongside one another on a substrate and are connected by a bridge die embedded in the substrate. In the EMIB structure, there may be a problem in that the bridge die is positioned below the logic die, thereby increasing the package thickness and heat generation of the logic die may cause a degradation in the performance of memory dies adjacent thereto. Further, as buffer dies have been developed to meet customer needs such as the use of a front-end logic process, the yield of buffer dies may make it difficult to manufacture high bandwidth memories by a chip-on-wafer (CoW) process.

According to the present disclosure, by disposing the bridge die 700 alongside the memory stack on the buffer die 200 and the logic die 300, it is possible to provide a semiconductor package 1000A with a reduced thickness. Further, by dissipating heat generated by the buffer die 200 and/or the logic die 300 to the outside of the package through the bridge die 700, it is possible to provide a semiconductor package 1000A with improved heat dissipation. Furthermore, it is possible to provide a semiconductor package 1000A capable of an efficient connection between the buffer die 200 and the memory stack 600.

The semiconductor package 1000A may further include a dummy die 701 that is disposed on the bridge die 700. The dummy die 701 may be disposed adjacent to the memory stack 600, on the same level. The dummy die 701 may form a heat dissipation path along with the bridge die 700, thereby improving heat dissipation of the semiconductor package 1000A. For example, the heat generated by the buffer die 200 and/or the logic die 300 may be dissipated through the dummy die 701. The dummy die 701 may be a semiconductor substrate 210 such as a silicon substrate, and may include an adhesive, such as a die attach film (DAF) between the bridge die 700 and the dummy die 701. The memory stack 600 and the dummy die 701 may be exposed from the upper surface of the second encapsulating material 800 to provide better heat dissipation. However, in some embodiments, the upper surface of at least one of the memory stack 600 and the dummy die 701 may be covered by the second encapsulating material 800. In some embodiments, in place of the dummy die 701, a heat dissipation structure having excellent thermal conductivity (for example, a metal block such as Cu) may be disposed on the bridge die 700.

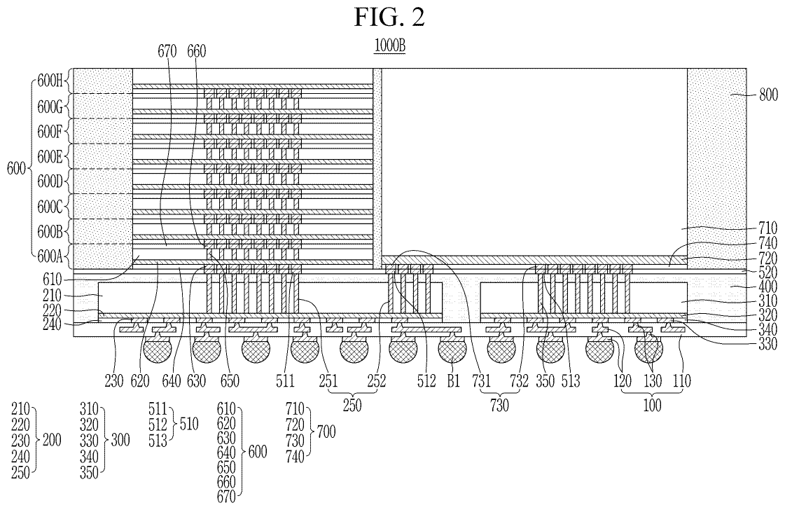

FIG. 2 is a cross-sectional view of a semiconductor package according to an embodiment.

A semiconductor package 1000B might not include a dummy die 701. For example, when the bridge die 700 is sufficiently thick, a dummy die 701 for improving heat dissipation might not be necessary. In order to provide excellent heat dissipation, the memory stack 600 and the bridge die 700 may be exposed from the upper surface of the second encapsulating material 800. However, in some embodiments, the upper surface of at least one of the memory stack 600 and the bridge die 700 may be covered by the second encapsulating material 800.

With respect to a description of the other components, the above contents described in the description of the semiconductor package 1000A, according to the embodiment of the present disclosure, may be equally applied and to the extent that an element is not described in detail with respect to this figure, it may be understood that the element is at least similar to a corresponding element that has been described elsewhere within the present disclosure.

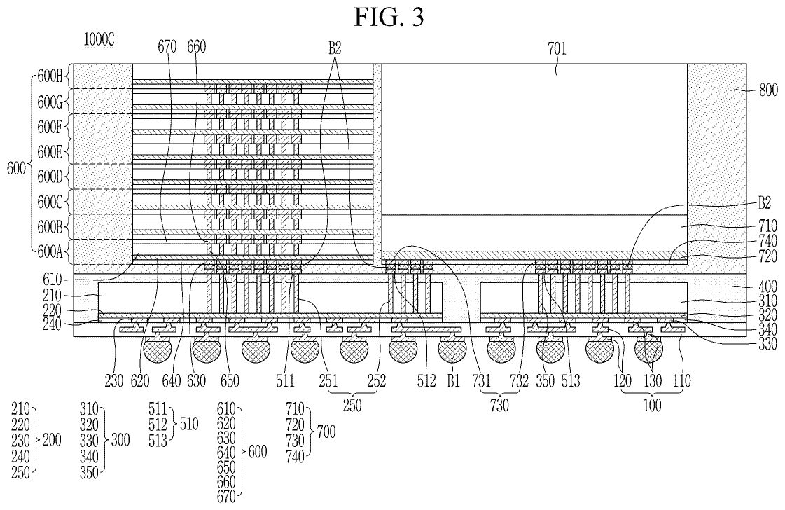

FIG. 3 is a cross-sectional view of a semiconductor package according to an embodiment.

The via pads 510 of a semiconductor package 1000C may be bonded to the memory stack 600 and the bridge die 700, respectively, by bump bonding. Accordingly, the semiconductor package 1000C may further include second conductive bumps B2 that are disposed between first connection pads 630 and the first via pads 511, between the second connection pads 731 and the second via pads 512, and between the third connection pads 732 and the third via pads 513, respectively, and provide electrical connections between them. The second conductive bumps B2 may include a conductive material, and may include, for example, solder.

With respect to a description of the other components, the above contents described in the description of the semiconductor package 1000A, according to the embodiment of the present disclosure, may be equally applied and to the extent that an element is not described in detail with respect to this figure, it may be understood that the element is at least similar to a corresponding element that has been described elsewhere within the present disclosure.

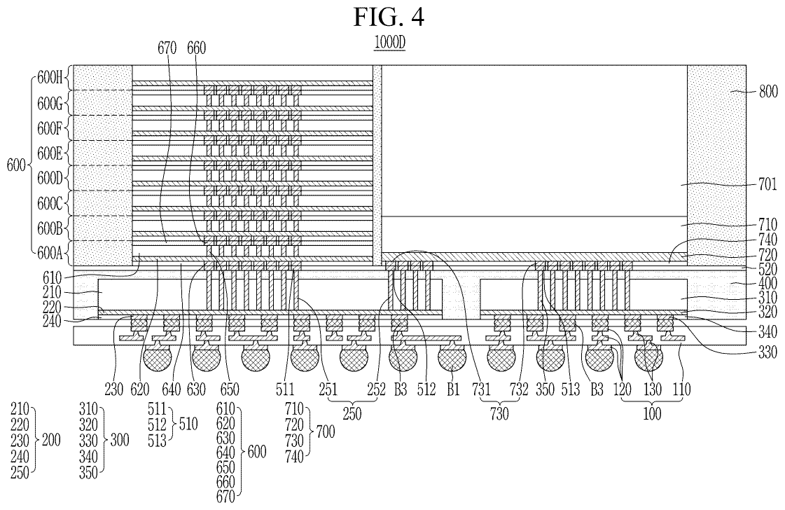

FIG. 4 is a cross-sectional view of a semiconductor package according to an embodiment.

Each of the buffer die 200 and the logic die 300 of a semiconductor package 1000D may be bonded to the wiring structure 100 by bump bonding. Accordingly, the semiconductor package 1000D may further include conductive bumps B3 that are disposed between each of the buffer die 200 and the logic die 300 and the wiring structure 100 and provide electrical connections between them. The conductive bumps B3 may include a conductive material, and may include, for example, solder.

With respect to a description of the other components, the above contents described in the description of the semiconductor package 1000A according to the embodiment of the present disclosure may be equally applied and to the extent that an element is not described in detail with respect to this figure, it may be understood that the element is at least similar to a corresponding element that has been described elsewhere within the present disclosure.

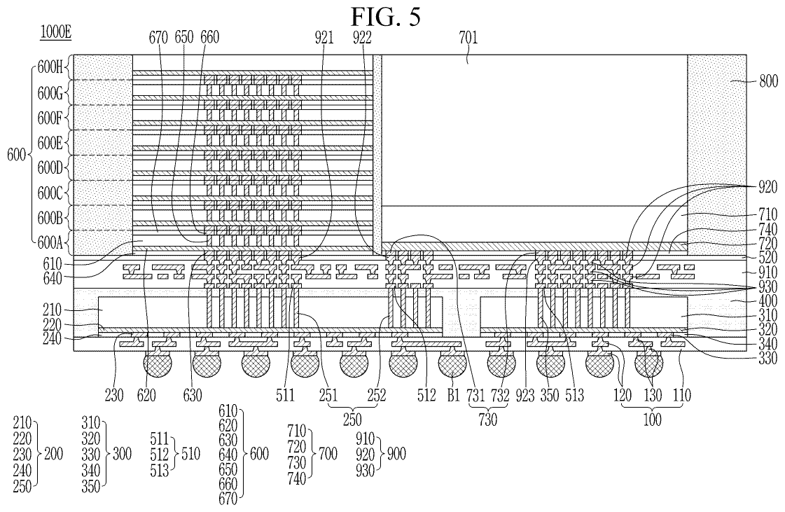

FIG. 5 is a cross-sectional view of a semiconductor package according to an embodiment.

A semiconductor package 1000E may further include an additional wiring structure 900 that is disposed so as to extend between the buffer die 200 and the logic die 300, and the memory stack 600 and the bridge die 700, and is electrically connected to the buffer die 200, the logic die 300, the memory stack 600, and the bridge die 700. In the following description, the additional wiring structure 900 will be referred to as the second wiring structure 900 to distinguish from the wiring structure 100.

In the embodiment, the second wiring structure 900 may be disposed so as to extend between the via pads 510 and the memory stack 600 and between the via pads 510 and the bridge die 700. Further, the second wiring structure 900 may be electrically connected to the via pads 510, the memory stack 600, and the bridge die 700.

The second wiring structure 900 may include an insulating layer 910, a wiring layer 920, and vias 930. The insulating layer 910 may cover the via pads 510. Since the insulating layer 520 for hybrid bonding is disposed on the insulating layer 910, it may be preferable for the insulating layer 910 to include an inorganic material such as a silicon oxide or a silicon nitride. However, in some embodiments, the insulating layer 910 may include an organic material, for example, a thermosetting resin like polyimide, a thermoplastic resin such as epoxy, a photo-imageable dielectric (PID), etc. With respect to other descriptions of each of the insulating layer 910, the wiring layer 920, and the vias 930 of the second wiring structure 900, the description of the insulating layer 110, the wiring layer 120, and the vias 130 of the wiring structure 100 may be equally applied unless particularly contradicted and to the extent that an element is not described in detail with respect to this figure, it may be understood that the element is at least similar to a corresponding element that has been described elsewhere within the present disclosure.

With respect to a description of the other components, the above contents described in the description of the semiconductor package 1000A, according to the embodiment of the present disclosure, may be equally applied and to the extent that an element is not described in detail with respect to this figure, it may be understood that the element is at least similar to a corresponding element that has been described elsewhere within the present disclosure.

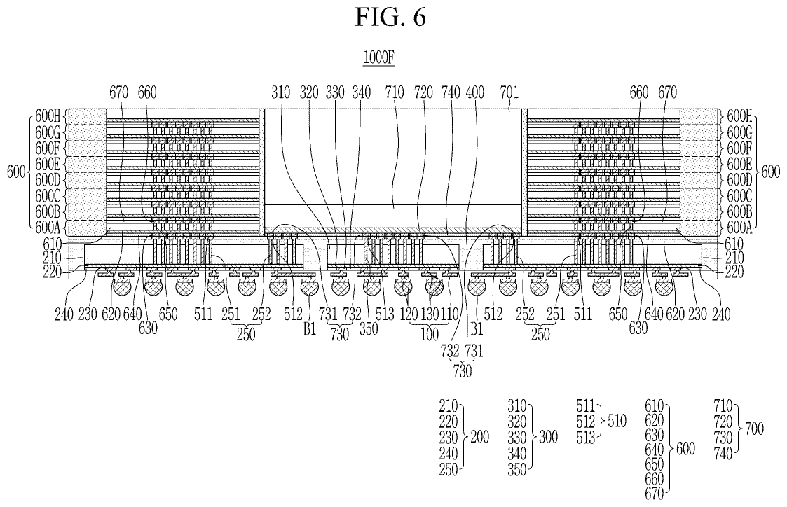

FIG. 6 is a cross-sectional view of a semiconductor package according to an embodiment.

A semiconductor package 1000F may include a plurality of buffer dies 200 and a plurality of memory stacks 600. For example, the plurality of buffer dies 200 may be disposed on both sides of the logic die 300 and be connected to the bridge die 700, and the plurality of memory stacks 600 may be disposed on the plurality of buffer dies 200, respectively.

With respect to a description of the other components, the above contents described in the description of the semiconductor package 1000A according to the embodiment of the present disclosure may be equally applied and to the extent that an element is not described in detail with respect to this figure, it may be understood that the element is at least similar to a corresponding element that has been described elsewhere within the present disclosure.

FIGS. 7 to 15 are views illustrating a process of manufacturing a semiconductor package according to an embodiment.

A semiconductor package manufacturing method according to an embodiment includes a step of disposing a buffer die 200 including first through-vias 251 and second through-vias 252 and a logic die 300 including third through-vias 350 alongside one another. The buffer die 200 and the logic die 300 may be encapsulated with the first encapsulating material 400. Via pads 510, which include first via pads 511 that are connected to the first through-vias 251, second via pads 512 that are connected to the second through-vias 252, and third via pads 513 that are connected to the third through-vias 350, may be formed on the first encapsulating material 400. A memory stack 600 may be disposed on the first encapsulating material 400 such that first connection pads 630 of the memory stack 600 are electrically connected to the first via pads 511. A bridge die 700 may be disposed on the first encapsulating material 400 such that second connection pads 731 and third connection pads 732 of the memory stack 600 are electrically connected to the second via pads 512 and the third via pads 513, respectively. A second encapsulating material 800 may be formed to cover at least a portion of each of the memory stack 600 and the bridge die 700. A wiring structure 100 which is electrically connected to the buffer die 200 and the logic die 300 may be formed.

First, referring to FIG. 7, the buffer die 200 including the first through-vias 251 and the second through-vias 252 and the logic die 300 including the third through-vias 350 are disposed alongside one another. The buffer die 200 and the logic die 300 may be disposed on the carrier substrate 10, and may be disposed face down such that their connection pads 230 and 330 face the carrier substrate 10. The arrangement order of the buffer die 200 and the logic die 300 is not necessarily limited to what is described herein.

The upper ends the through-vias 250 of the buffer die 200 may be embedded in the semiconductor substrate 210, and/or the third through-vias 350 of the logic die 300 may be embedded in the semiconductor substrate 310. Accordingly, as shown in FIG. 8, a process for explaining the upper ends of the through-vias 250 of the buffer die 200 and the third through-vias 350 of the logic die 300 may be additionally performed. For example, a process of processing the back surface 210B of the semiconductor substrate 210 through which the first through-vias 251 and the second through-vias 252 of the buffer die 200 penetrate, such that a portion of each of the first through-vias 251 and the second through-vias 252 protrude from the back surface 210B of the semiconductor substrate 210, and processing the back surface 310B of the semiconductor substrate 310 through which the third through-vias 350 of the logic die 300 penetrate, such that portions of the third through-vias protrude from the back surface 310B of the semiconductor substrate 310 may be performed. The processing of the back surface 210B of the semiconductor substrate 210 and the back surface 310B of the semiconductor substrate 310 may be performed by dry etching. In the present disclosure, for ease of explanation, the same reference symbols are used for the back surfaces 210B and 310B of the semiconductor substrates 210 and 310 before and after the processing and it is to be understood that their properties have changed.

Subsequently, referring to FIGS. 9 and 10, the buffer die 200 and the logic die 300 are encapsulated with the first encapsulating material 400, and the first encapsulating material 400 is ground so as to expose the first through-vias 251, the second through-vias 252, and the third through-vias 350. After the encapsulating (e.g., before the grinding), the first encapsulating material 400 may cover the upper surface of the buffer die 200 and the upper surface of the logic die 300, and may further cover the upper end of each of the first through-vias 251, the second through-vias 252, and the third through-vias 350. The grinding of the first encapsulating material 400 may be performed by, for example, a chemical mechanical polishing (CMP) process. The first encapsulating material 400 may extend to the upper surface of each of the buffer die 200 and the logic die 300 so as to cover the semiconductor substrates 210 and 310, thereby preventing the semiconductor substrates 210 and 310 from being contaminated by processing the first encapsulating material 400 and/or the through-vias 250 and 350 during the process of grinding the first encapsulating material 400.

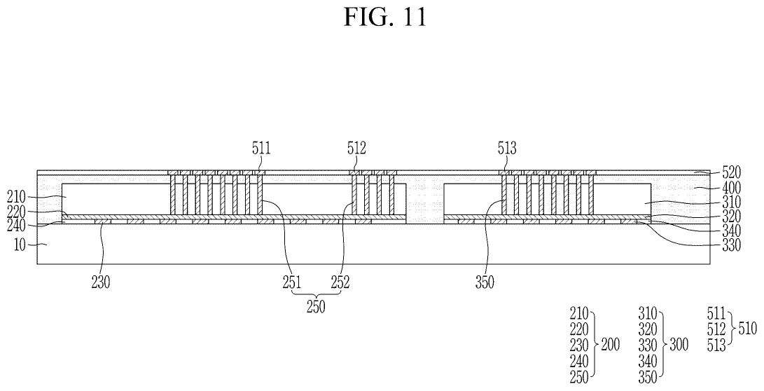

Subsequently, referring to FIG. 11, the via pads 510 and the insulating layer 520 for serving as bonding layers for hybrid bonding are formed on the first encapsulating material 400. The via pads 510 include first via pads 511 that are connected to the first through-vias 251, second via pads 512 that are connected to the second through-vias 252, and third via pads 513 that are connected to the third through-vias 350.

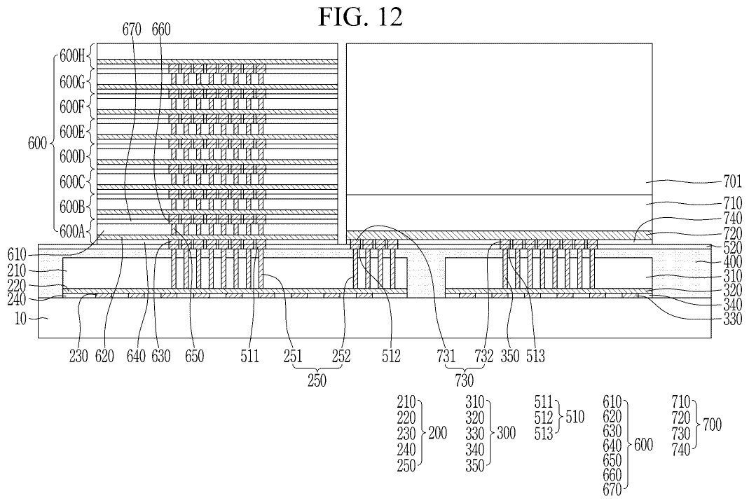

Subsequently, referring to FIG. 12, the memory stack 600 and the bridge die 700 are disposed on the first encapsulating material 400. The memory stack 600 and the bridge die 700 may be disposed alongside one another, but the arrangement order between them is not necessarily limited to what is described herein.

At this time, the first connection pads 630 of the memory stack 600 are electrically connected to the first via pads 511, and, for example, the first connection pads 630 may be in contact with and bonded to the first via pads 511 by hybrid bonding. Similarly, the second connection pads 731 and the third connection pads 732 of the bridge die 700 are electrically connected to the second via pads 512 and the third via pads 513, respectively, and, for example, the second connection pads 731 and the third connection pads 732 of the bridge die 700 may be in contact with and bonded to the second via pads 512 and the third via pads 513, respectively, by hybrid bonding.

If necessary, a dummy die 701 may be additionally disposed on the bridge die 700. For example, the dummy die 701 may be attached to the bridge die 700 through an adhesive such as a die attach film (DAF).

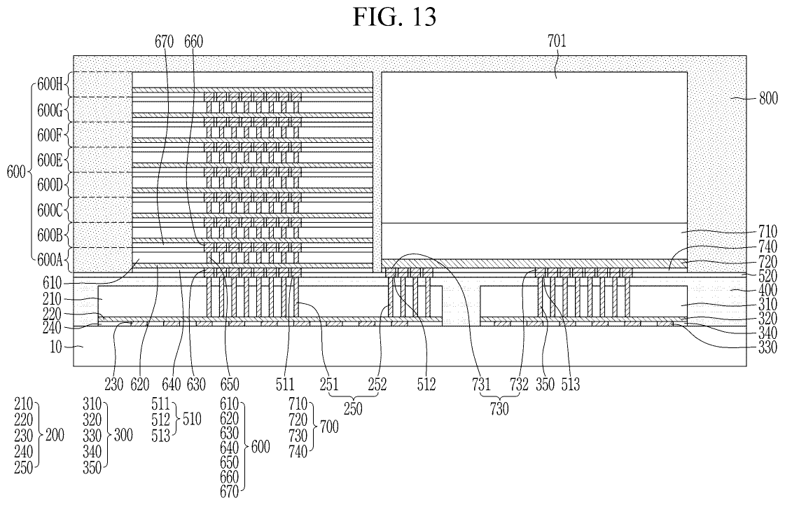

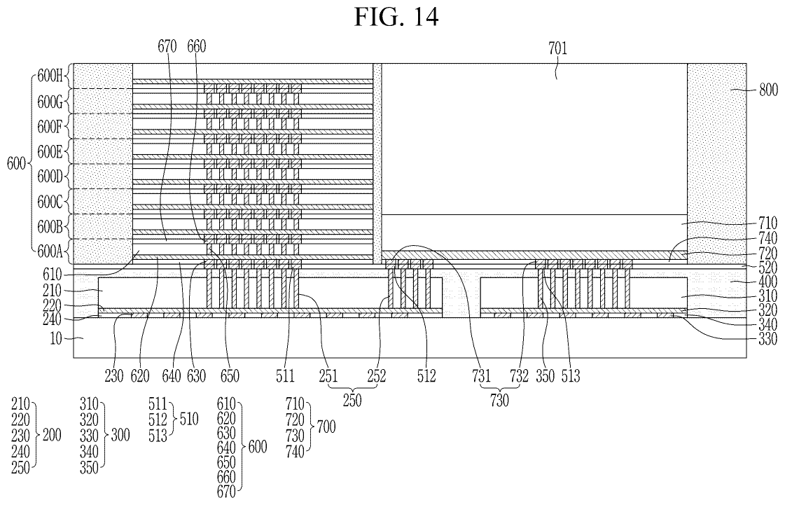

Subsequently, referring to FIGS. 13 and 14, a second encapsulating material 800 is formed so as to cover at least a portion of each of the memory stack 600, the bridge die 700, and the dummy die 701, and the second encapsulating material 800 is ground so as to expose the memory stack 600 and the dummy die 701.

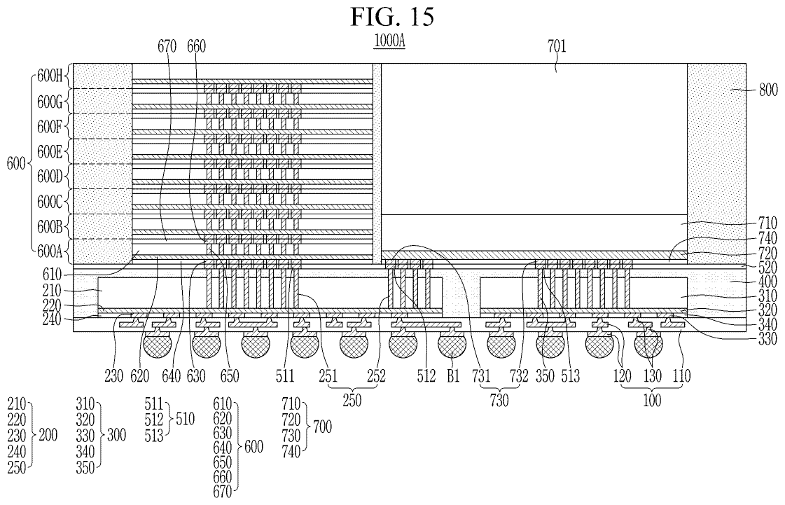

Finally, referring to FIG. 15, the carrier substrate 10 is removed, and a wiring structure 100 is formed on the surfaces of the buffer die 200 and the logic die 300 from which the carrier substrate 10 has been removed, so as to be electrically connected to the buffer die 200 and the logic die 300. The wiring structure 100 may be formed by repeatedly performing a process of forming an insulating layer 110, vias 130, and a wiring layer 120 if necessary. If necessary, conductive bumps B1 may be attached to the wiring structure 100.

While this disclosure has been described in connection with what is presently considered to be practical embodiments, it is to be understood that the disclosure is not necessarily limited to the disclosed embodiments. On the contrary, it is intended to cover various modifications and equivalent arrangements.

Further, the embodiments of the present disclosure are not necessarily independent from one another, and may be implemented in combination with one another. Accordingly, it will be appreciated that forms which are implemented by combining the embodiments of the present disclosure are also included in the present disclosure.

What is claimed is:

1. A semiconductor package, comprising:
a wiring structure;
a buffer die disposed on the wiring structure;
a logic die disposed alongside the buffer die on the wiring structure;
a first encapsulating material covering at least a portion of each of the buffer die and the logic die;
a memory stack disposed on the buffer die and electrically connected to the buffer die;
a bridge die extending over at least a portion of each of the buffer die and the logic die, and electrically connected to each of the buffer die and the logic die; and
a second encapsulating material covering at least a portion of each of the memory stack and the bridge die,
wherein the buffer die and the logic die are disposed at a level between those of the wiring structure and the bridge die.

2. The semiconductor package of claim 1, wherein:
the bridge die is disposed alongside the memory stack.

3. The semiconductor package of claim 1, wherein:
the bridge die overlaps an entirety of the logic die.

4. The semiconductor package of claim 1, wherein:
the memory stack and the bridge die are exposed from an upper surface of the second encapsulating material.

5. The semiconductor package of claim 1, further comprising:
a dummy die disposed on the bridge die.

6. The semiconductor package of claim 5, wherein:
the memory stack and the dummy die are exposed from an upper surface of the second encapsulating material.

7. A semiconductor package, comprising:
a first wiring structure;
a buffer die disposed on the first wiring structure, and including first through-vias and second through-vias;
a logic die disposed alongside the buffer die on the first wiring structure, and including third through-vias;
a first encapsulating material covering at least a portion of each of the buffer die and the logic die;
via pads disposed on the first encapsulating material, and including first via pads connected to the first through-vias, second via pads connected to the second through-vias, and third via pads connected to the third through-vias;
a memory stack disposed on the first encapsulating material, and including first connection pads electrically connected to the first via pads;
a bridge die disposed alongside the memory stack on the first encapsulating material, and including second connection pads and third connection pads electrically connected to the second via pads and the third via pads, respectively; and
a second encapsulating material covering at least a portion of each of the memory stack and the bridge die.

8. The semiconductor package of claim 7, wherein:
a portion of each of the first through-vias and the second through-vias protrudes from an upper surface of the buffer die, and
portions of the third through-vias protrude from an upper surface of the logic die.

9. The semiconductor package of claim 8, wherein:
the first encapsulating material extends over each of the buffer die and the logic die so as to cover at least a portion of the protruding portion of each of the first through-vias, the second through-vias, and the third through-vias.

10. The semiconductor package of claim 7, wherein:
the first connection pads, the second connection pads, and the third connection pads are in contact with and connected to the first via pads, the second via pads, and the third via pads, respectively.

11. The semiconductor package of claim 10, further comprising:
a first insulating layer disposed on the first encapsulating material and in which the first via pads, the second via pads, and the third via pads are embedded,
wherein the memory stack further includes a second insulating layer in which the first connection pads are embedded,
wherein the bridge die further includes a third insulating layer in which the second connection pads and the third connection pads are embedded, and
wherein the first insulating layer is in contact with each of the second insulating layer and the third insulating layer.

12. The semiconductor package of claim 11, wherein:
the first encapsulating material and the first insulating layer each include an inorganic material.

13. The semiconductor package of claim 7, further comprising:
conductive bumps disposed between the first connection pads and the first via pads, between the second connection pads and the second via pads, and between the third connection pads and the third via pads.

14. The semiconductor package of claim 7, wherein:
the first wiring structure includes vias that are in contact with and connected to the buffer die and the logic die, respectively.

15. The semiconductor package of claim 7, further comprising:
conductive bumps disposed between each of the buffer die and the logic die and the first wiring structure.

16. The semiconductor package of claim 7, further comprising:
a second wiring structure that is disposed so as to extend between the via pads and the memory stack and between the via pads and the bridge die, and is electrically connected to the first, second, and third via pads, the memory stack, and the bridge die.

17. A semiconductor package manufacturing method, comprising:
disposing a buffer die alongside a logic die, the buffer die including first through-vias and second through-vias and the logic die including third through-vias;
encapsulating the buffer die and the logic die with a first encapsulating material;
forming via pads, which include first via pads connected to the first through-vias, second via pads connected to the second through-vias, and third via pads connected to the third through-vias, on the first encapsulating material;
disposing a memory stack on the first encapsulating material such that first connection pads of the memory stack are electrically connected to the first via pads;
disposing a bridge die on the first encapsulating material such that second connection pads and third connection pads of the bridge die are electrically connected to the second via pads and the third via pads, respectively;
forming a second encapsulating material covering at least a portion of each of the memory stack and the bridge die; and
forming a wiring structure electrically connected to the buffer die and the logic die.

18. The semiconductor package manufacturing method of claim 17, further comprising:
processing a back surface of a first semiconductor substrate through which the first through-vias and the second through-vias of the buffer die penetrate, such that a portion of each of the first through-vias and the second through-vias protrudes from the back surface of the first semiconductor substrate; and
processing a back surface of a second semiconductor substrate through which the third through-vias of the logic die penetrate, such that portions of the third through-vias protrude from the back surface of the second semiconductor substrate.

19. The semiconductor package manufacturing method of claim 18, further comprising:
grinding the first encapsulating material to expose the first through-vias, the second through-vias, and the third through-vias.

20. The semiconductor package manufacturing method of claim 17, wherein:
in disposing the memory stack on the first encapsulating material, the first connection pads of the memory stack are in contact with and bonded to the first via pads, and
in disposing the bridge die on the first encapsulating material, the second connection pads and the third connection pads of the bridge die are in contact with and bonded to the second via pads and the third via pads, respectively.
